(19) United States
(12) Patent Application Publication
(10) Pub. No.: US 2026/0225897 A1
(43) Pub. Date: Aug. 6, 2026

(54) COPPER-DOPED SILICON CARBIDE COMPOSITE, PREPARATION METHOD AND USE THEREOF

(71) Applicant: ZHEJIANG UNIVERSITY, Zheijang (CN)

(72) Inventors: Qiwei YANG, Zhejiang (CN); Chen WANG, Zhejiang (CN); Wenjun ZHANG, Zhejiang (CN); Qilong REN, Zhejiang (CN); Zhiguo ZHANG, Zhejiang (CN); Zongbi BAO, Zhejiang (CN); Baogen SU, Zhejiang (CN)

(21) Appl. No.: 19/641,445

(22) Filed: Apr. 7, 2026

Related U.S. Application Data
(63) Continuation of application No. PCT/CN2025/133652, filed on Nov. 8, 2025.

(30) Foreign Application Priority Data
Sep. 9, 2024 (CN) 202411252473.0

(51) Int. Cl. C01B 32/977

(52) U.S. Cl. CPC C01B 32/977; C01P 2002/54; C01P 2002/72; C01P 2002/77; C01P 2004/04; C01P 2004/62; C01P 2004/64

(57) ABSTRACT

Provided are a copper-doped silicon carbide composite, a preparation method and use thereof. The preparation method for the copper-doped silicon carbide composite includes subjecting a silicon- and carbon-containing precursor to arc plasma pyrolysis to obtain the copper-doped silicon carbide composite, where the silicon-and carbon-containing precursor includes an organochlorosilane; and a material of an anode used for the arc plasma pyrolysis includes copper.

### CROSS REFERENCE TO RELATED APPLICATION

The present application is a continuation application of International Patent Application No. PCT/CN 2025/133652, filed on Nov. 8, 2025, which claims priority to the Chinese Patent Application No. 202411252473.0, filed with the China National Intellectual Property Administration on Sep. 9, 2024 and entitled “COPPER-DOPED SILICON CARBIDE COMPOSITE, PREPARATION METHOD AND USE THEREOF”. The contents of the two applications each are incorporated herein by reference.

### TECHNICAL FIELD

The present disclosure belongs to the technical field of electromagnetic wave-absorbing materials, and in particular relates to a copper-doped silicon carbide composite, a preparation method and use thereof.

### BACKGROUND

Electromagnetic waves play a pivotal role in modern information-driven life. However, the widespread proliferation of electronic devices driven by technological advancements has led to pervasive electromagnetic waves that may cause electromagnetic pollution to some extent, which interferes with the operation of precision instruments and poses potential hazards to human health. With the development of national defense construction, increasingly stringent requirements have been placed on the stealth capabilities of weaponry and military facilities. Therefore, the study of high-performance wave-absorbing materials is of great significance for both national defense and civilian sectors. To solve these problems, researchers have developed electromagnetic wave-absorbing materials capable of converting electromagnetic energy into heat or other forms of energy, dissipating electromagnetic radiation at the source. This enables protection of the human health and improvement of the device performance.

Electromagnetic wave-absorbing materials can effectively absorb electromagnetic waves into their matrix, achieving efficient attenuation. Their fundamental mechanism lies in converting the energy of electromagnetic waves into internal energy for dissipation. Depending on different wave-absorbing mechanisms, currently common electromagnetic wave-absorbing materials include magnetic loss materials and dielectric loss materials. Silicon carbide-based materials are typical dielectric loss materials, yet their intrinsic wave absorption performance is limited.

### SUMMARY

In view of this, the present disclosure is to provide a copper-doped silicon carbide composite, a preparation method and use thereof. The copper-doped silicon carbide composite prepared in the present disclosure shows excellent electromagnetic wave absorption performance and a broad effective absorption bandwidth.

In order to achieve the above object, the present disclosure provides following technical solutions.

The present disclosure provides a method for preparing a copper-doped silicon carbide composite, including:
subjecting a silicon- and carbon-containing precursor to arc plasma pyrolysis to obtain the copper-doped silicon carbide composite, where the silicon-and carbon-containing precursor includes an organochlorosilane; and a material of an anode used for the arc plasma pyrolysis includes copper.

In some embodiments, the arc plasma pyrolysis is conducted with an arc power of 1-100 kW.

In some embodiments, an arc-striking atmosphere gas for the arc plasma pyrolysis includes at least one selected from the group consisting of argon, nitrogen, hydrogen and helium.

In some embodiments, a flow rate of the arc-striking atmosphere gas is in a range of 0.2-30 L/min.

In some embodiments, the organochlorosilane includes at least one selected from the group consisting of methyltrichlorosilane, dimethyldichlorosilane, and trimethylchlorosilane.

In some embodiments, a feed rate of the silicon-and carbon-containing precursor is in a range of 0.1-2000 g/min.

In some embodiments, after the arc plasma pyrolysis, the method further includes subjecting a resulting solid product to alkaline washing and drying in sequence to obtain the copper-doped silicon carbide composite.

The present disclosure provides a copper-doped silicon carbide composite prepared by the method described in the aforementioned technical solutions.

In some embodiments, silicon carbide in the copper-doped silicon carbide composite has a β-type crystal form.

In some embodiments, the copper-doped silicon carbide composite has a particle size of 20-500 nm.

In some embodiments, copper in the copper-doped silicon carbide composite is doped in a SiC lattice in a form of a copper-silicon solid solution; and
the copper-silicon solid solution includes Cu_{6.69}Si and/or Cu₃Si.

The present disclosure provides use of the copper-doped silicon carbide composite described in the above technical solutions in a wave-absorbing material.

In some embodiments, the wave-absorbing material is an electromagnetic wave-absorbing material.

In some embodiments, the wave-absorbing material is a microwave-absorbing material.

The present disclosure provides a method for preparing a copper-doped silicon carbide composite. In the present disclosure, copper is used as a material of an anode, and the organochlorosilane is introduced as a raw material. During preparation of silicon carbide, the high reactivity of a chlorine plasma is utilized to induce thermal excitation and chemical reaction-based stripping of copper anode. This process enables copper to incorporate into lattices of the silicon carbide, resulting in production of the copper-doped silicon carbide composite. In the present disclosure, an electrical conductivity and magnetic properties of copper provide excellent electromagnetic wave absorption performance within a microwave frequency range. This allows for effective conversion of electromagnetic wave energy into thermal energy, thereby reducing or eliminating reflection and transmission and enhancing the absorption rate of the material. Further, copper doping can introduce extra interfaces and lattice defects, which increase the electromagnetic energy loss channels of the material. These multiple loss mechanisms are conducive to broadening the absorption bandwidth of the copper-doped silicon carbide composite. The copper-doped silicon carbide composite prepared in the present disclosure shows excellent microwave absorption performance and a broad effective absorption bandwidth. The preparation method provided in the present disclosure is simple and suitable for widespread promotion and application.

Some embodiments of the present disclosure have the following beneficial effects:

In the present disclosure, the organochlorosilane is used as the silicon-and carbon-containing precursor, which is cost-effective, safe, and highly efficient and can provide both silicon and carbon for the preparation of the silicon carbide; and a chlorine element forms the chlorine plasma in plasma, which has higher activity and can excite more copper to enter the system.

The present disclosure utilizes dual effects of the arc thermal excitation and high reactivity of the chlorine plasma to achieve copper doping into the silicon carbide.

In the present disclosure, dielectric parameters of the copper-doped silicon carbide composite are obtained by means of a vector network analyzer. Based on the transmission line theory, the calculated results demonstrate that the copper-doped silicon carbide composite possesses excellent wave absorption performance and a broad wave absorption bandwidth.

The method described in the present disclosure is continuous and efficient, and is a synthesis method suitable for large-scale use.

### BRIEF DESCRIPTION OF THE DRAWINGS

FIG. 1 shows a schematic diagram illustrating the preparation principle of the copper-doped silicon carbide composite according to an embodiment of the present disclosure;

FIG. 2 shows x-ray diffraction (XRD) patterns of the copper-doped silicon carbide composites prepared in Examples 1-3 of the present disclosure;

FIG. 3 shows a transmission electron microscope (TEM) image of the copper-doped silicon carbide composite prepared in Example 1 of the present disclosure;

FIG. 4 shows high-resolution transmission electron microscope (HRTEM) images of the copper-doped silicon carbide composite prepared in Example 1 of the present disclosure;

FIG. 5 shows a graph illustrating the reflection loss value of the copper-doped silicon carbide composite prepared in Example 1 of the present disclosure;

FIG. 6 shows a graph illustrating the real part value of the dielectric loss of the copper-doped silicon carbide composite prepared in Example 1 of the present disclosure;

FIG. 7 shows a graph illustrating the imaginary part value of the dielectric loss of the copper-doped silicon carbide composite prepared in Example 1 of the present disclosure;

FIG. 8 shows a graph illustrating the dielectric loss tangent value of the copper-doped silicon carbide composite prepared in Example 1 of the present disclosure;

FIG. 9 shows a graph illustrating the real part value of the magnetic loss of the copper-doped silicon carbide composite prepared in Example 1 of the present disclosure;

FIG. 10 shows a graph illustrating the imaginary part value of the magnetic loss of the copper-doped silicon carbide composite prepared in Example 1 of the present disclosure;

FIG. 11 shows a graph illustrating the imaginary loss tangent value of the copper-doped silicon carbide composite prepared in Example 1 of the present disclosure;

FIG. 12 shows a schematic structural diagram of an arc plasma generator;

FIG. 13 shows a graph illustrating the reflection loss value of the copper-doped silicon carbide composite prepared in Example 2; and

FIG. 14 shows a graph illustrating the reflection loss value of the copper-doped silicon carbide composite prepared in Example 3.

### DETAILED DESCRIPTION OF THE EMBODIMENTS

The present disclosure provides a method for preparing a copper-doped silicon carbide composite, including:
subjecting a silicon-and carbon-containing precursor to arc plasma pyrolysis to obtain the copper-doped silicon carbide composite, where the silicon-and carbon-containing precursor includes an organochlorosilane; and a material of an anode used for the arc plasma pyrolysis includes copper.

Unless otherwise specified, the materials and equipment used in the present disclosure are commercially available in the art.

The present disclosure involves subjecting a silicon-and carbon-containing precursor to the arc plasma pyrolysis to obtain the copper-doped silicon carbide composite.

In the present disclosure, the silicon-and carbon-containing precursor includes the organochlorosilane. In the present disclosure, the organochlorosilane preferably includes at least one selected from the group consisting of methyltrichlorosilane, dimethyldichlorosilane, and trimethylchlorosilane. In the present disclosure, a feed rate of the silicon-and carbon-containing precursor is preferably in a range of 0.1-2000 g/min, more preferably 0.175-2 g/min, and further preferably 0.5-1 g/min. In a specific embodiment, the feed rate of the silicon- and carbon-containing precursor may be 0.5 g/min, 1 g/min, 2 g/min, 100 g/min, 500 g/min, 1000 g/min, or 1500 g/min. In the present disclosure, a carbon-containing chlorosilane is used as the silicon- and carbon-containing precursor for preparing silicon carbide. Meanwhile, the chlorine element forms a highly active chlorine plasma state in a plasma environment, which is conducive to improving copper doping rate and doping effect.

In the present disclosure, a material of an anode used for the arc plasma pyrolysis includes copper, and specifically, a copper sleeve is preferred.

In the present disclosure, an arc power of the arc plasma pyrolysis is preferably 1-100 kW, more preferably 2-10 kW, and further preferably 5-8 kW. In a specific embodiment, the arc power of the arc plasma pyrolysis may be 1.6 kW, 2.2 kW, 2.9 kW, 10 kW, 20 kW, 30 kW, 40 kW, 50 kW, 60 kW, 70 kW, 80 kW, or 90 kW.

In the present disclosure, an arc-striking atmosphere gas for the arc plasma pyrolysis preferably includes at least one selected from the group consisting of argon, nitrogen, hydrogen and helium, and more preferably is argon. In the present disclosure, a flow rate of the arc-striking atmosphere gas for the arc plasma pyrolysis is preferably in a range of 0.2-30 L/min, more preferably 1-20 L/min, and further preferably 2-10 L/min. In a specific embodiment, the flow rate of the arc-striking atmosphere gas for the arc plasma pyrolysis may be 1 L/min, 2 L/min, 5 L/min, 10 L/min, 15 L/min, 20 L/min or 25 L/min. In the present disclosure, the arc-striking atmosphere gas above is used to create the reaction atmosphere, and the reaction pressure is controlled to generate an arc.

In the present disclosure, after the arc plasma pyrolysis, the method preferably further includes subjecting a resulting solid product to alkaline washing and drying in sequence to obtain the copper-doped silicon carbide composite. In a specific embodiment of the present disclosure, a gaseous copper-doped silicon carbide is formed after the arc plasma pyrolysis; and the gaseous copper-doped silicon carbide is cooled into the resulting solid product in the arc plasma generator. In the present disclosure, an alkaline solution used for the alkaline washing is preferably a NaOH solution; and the NaOH solution preferably has a concentration of 0.01-1 mol/L, more preferably 0.1-0.5 mol/L. In the present disclosure, an amount ratio of the resulting solid product to the NaOH solution is preferably 2 g: 100 mL. In the present disclosure, the alkaline washing is preferably conducted under ultrasonic conditions for preferably 30 min. In the present disclosure, the alkaline washing is performed to remove HCl and residual raw materials adsorbed on a surface of the resulting solid product. The method of the present disclosure preferably includes conducting rinsing and suction filtration after the alkaline washing. In the present disclosure, a washing liquid used for the rinsing and suction filtration is preferably water, and more preferably deionized water. In a specific embodiment of the present disclosure, the rinsing and suction filtration refers to suction filtration with simultaneous rinsing. In the present disclosure, the drying is conducted at a temperature of preferably 105° C. for preferably 2 h. In the present disclosure, the drying is preferably conducted in a vacuum oven.

In a specific embodiment of the present disclosure, the arc plasma pyrolysis is conducted in an arc plasma generator; and structure of the arc plasma generator is shown in FIG. 12. The anode of the arc plasma generator is a copper sleeve and a cathode has a rod-like structure; and the cathode is made of graphite. In the present disclosure, the method for preparing the copper-doped silicon carbide composite preferably includes: using the organochlorosilane as a silicon- and carbon-containing precursor, and striking an arc in the presence of an arc-striking atmosphere gas; using the copper sleeve as the anode, and pyrolyzing the silicon-and carbon-containing precursor in the environment of a plasma using an arc plasma method to obtain a solid product; and subjecting the solid product to the alkaline washing using a NaOH solution to remove HCl and residual raw materials adsorbed on the surface of the solid product, followed by rinsing and suction filtration, and drying to obtain the copper-doped silicon carbide composite.

As an embodiment of the present disclosure, the method for preparing the copper-doped silicon carbide composite preferably includes: displacing air in the arc plasma generator with argon, and switching on a power supply to ignite the arc within the argon atmosphere; upon reaching a stable operating state, carrying methyltrichlorosilane from a bubbler into the arc plasma generator via argon and conducting pyrolysis to form a gaseous copper-doped silicon carbide, depositing the gaseous copper-doped silicon carbide within the arc plasma generator along the direction of a plasma jet, and collecting a resulting material to obtain the solid product; and subjecting the solid product to the alkaline washing using a NaOH solution to remove HCl and residual raw materials adsorbed on the surface of the solid product, followed by rinsing and suction filtration, and drying to obtain the copper-doped silicon carbide composite.

The present disclosure provides a copper-doped silicon carbide composite prepared by the method described in the aforementioned technical solutions. In the present disclosure, the silicon carbide in the copper-doped silicon carbide composite preferably has a β-type crystal form. In a specific embodiment of the present disclosure, silicon carbide in the copper-doped silicon carbide composite preferably is β-SiC. In the present disclosure, the copper-doped silicon carbide composite preferably is copper-doped nano silicon carbide composite; and the copper-doped silicon carbide composite preferably has a particle size of 20-500 nm, more preferably 50-100 nm. In the present disclosure, copper is doped into a SiC lattice in a form of a copper-silicon solid solution, replacing C atoms therein. In the present disclosure, the copper-silicon solid solution preferably includes at least one selected from the group consisting of Cu_{6.69}Si and Cu₃Si. In a specific embodiment of the present disclosure, due to an oxidation of Cl, copper-chlorine compounds such as CuCl₂ remaining on the surface are removed during the rinsing and suction filtration process.

The present disclosure provides use of the copper-doped silicon carbide composite described in the above technical solutions in a wave-absorbing material, preferably as an electromagnetic wave-absorbing material, and more preferably as a microwave-absorbing material.

The technical solutions in the present disclosure will be described clearly and completely below with reference to the examples of the present disclosure. Apparently, the described examples are merely some rather than all of the examples of the present disclosure. Based on the examples of the present disclosure, all other examples that would have been obtained by those of ordinary skill in the art without any creative efforts shall fall within the scope of the present disclosure.

The arc plasma generator used in the examples has a structure as shown in FIG. 12. The anode of the arc plasma generator is the copper sleeve and the cathode has a rod-like structure; and the cathode is made of graphite.

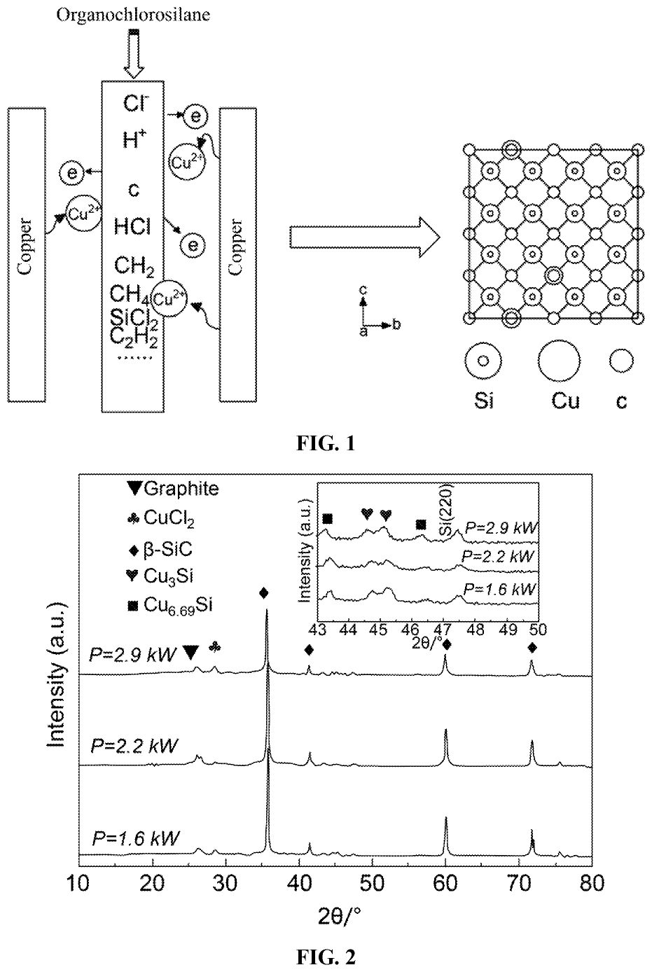

FIG. 1 shows a schematic diagram illustrating the principle of the preparation of the copper-doped silicon carbide composite using the organochlorosilane in a copper sleeve in an embodiment of the present disclosure.

### Example 1

Air in an arc plasma generator was displaced with argon, and the argon was continuously introduced at a flow rate of 2 L/min, and a power supply was switched on to ignite an arc within an argon atmosphere, with an arc power being set at 2.2 kW. Upon reaching a stable operating state, methyltrichlorosilane from a bubbler was carried, with a feed rate of 175 mg/min, into the arc plasma generator via argon, a resulting material was subjected to pyrolysis to form a gaseous copper-doped silicon carbide, and the gaseous copper-doped silicon carbide was deposited within the arc plasma generator along the direction of the plasma jet and collected to obtain a solid product.

2 g of the solid product was added to 100 mL of a NaOH solution with a concentration of 0.5 mol/L and sonicated for 30 min, followed by suction filtration with simultaneous washing with deionized water. A resulting solid was left to stand in a vacuum oven at 105° C. for 2 h to obtain a copper-doped silicon carbide composite.

### Example 2

A method was essentially the same as that in Example 1, except that an arc power was adjusted to 1.6 kW.

### Example 3

A method was essentially the same as that in Example 1, except that an arc power was adjusted to 2.9 kW.

### Test Example

### Examples 1-3 Illustrate the Effects of Different Arc Powers on Copper Doping Effect

FIG. 2 shows XRD patterns of copper-doped silicon carbide composites prepared under different arc power conditions in the present disclosure. As can be seen from FIG. 2, distinct characteristic peaks exist at 26.1°, 28.8°, 35.7°, 41.4°, 60.2°, and 71.8°. Among them, the peak at 26.1° corresponds to the diffraction from the (002) crystal plane of graphite, and the peak at 28.8° corresponds to the diffraction from the (111) crystal plane of CuCl₂; and the peaks at 35.7°, 41.4°, 60.2°and 71.8° correspond to the (111), (200), (220) and (311) crystal planes of β-SiC, respectively. Upon magnifying the range of 43°-50°, the peaks at 43.2° and 46.3° are observed to correspond to the (002) and (101) crystal planes of Cu_{6.69}Si; and the peaks at 44.6° and 45.2° correspond to the (012) and (300) crystal planes of Cu₃Si. This indicates the occurrence of multiple Cu-Si solid solutions in the composite. Due to its high diffusion coefficient, Cu can rapidly enter into the β-SiC lattice at high temperatures to achieve copper doping.

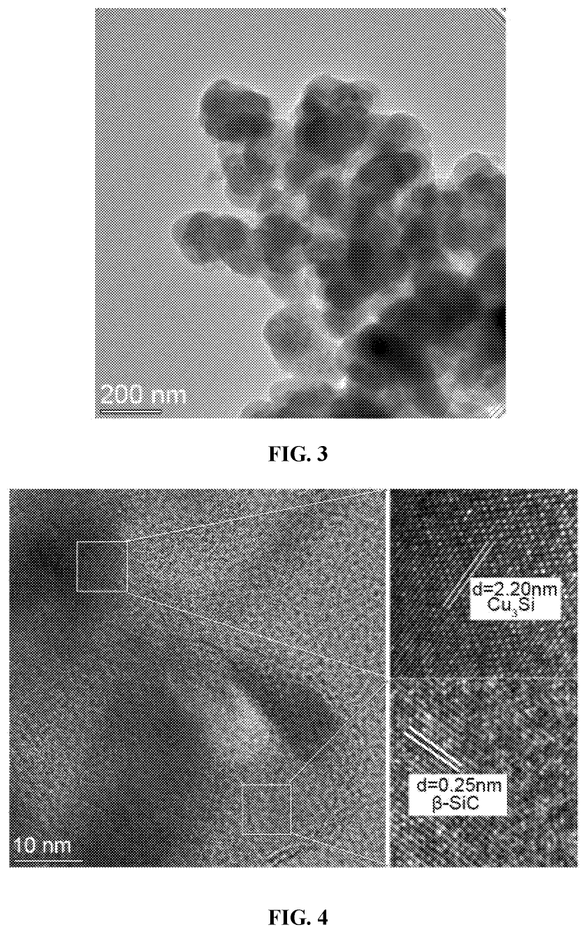

FIG. 3 shows a TEM image of the copper-doped silicon carbide composite prepared in Example 1 of the present disclosure. It is observed that the particles show distinct contrast differences, with those of darker appearance having a size of 10 nm or less.

FIG. 4 shows HRTEM images of the copper-doped silicon carbide composite prepared in Example 1 of the present disclosure. By comparing the parameters with standard cards, it can be confirmed that copper-silicon solid solutions are formed, demonstrating the feasibility of the method in the present disclosure for the preparation of a copper-doped silicon carbide composite.

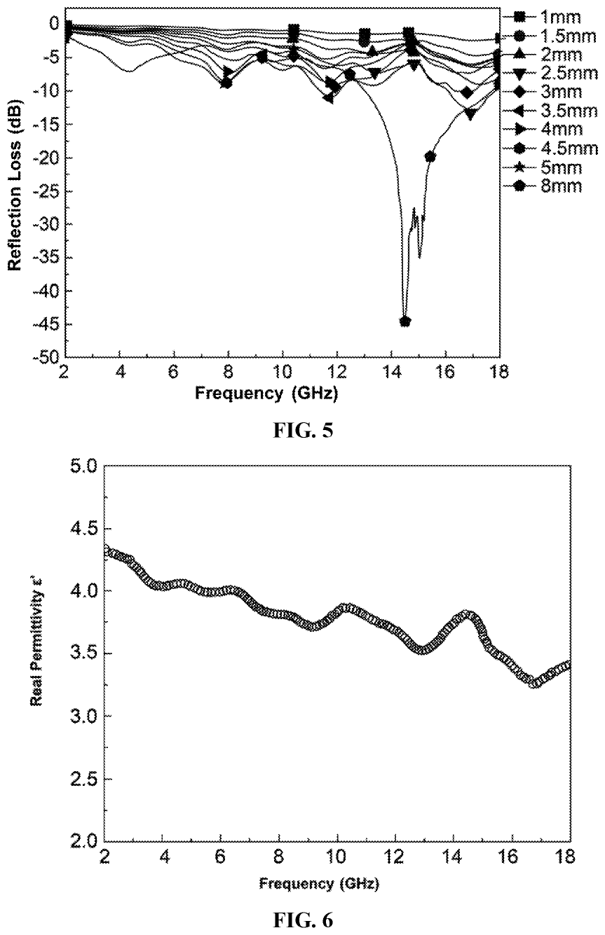

FIG. 5 shows a graph illustrating the reflection loss value of the copper-doped silicon carbide composite prepared in Example 1 of the present disclosure. As can be seen from the figure, the copper-doped silicon carbide composite achieves an RLmin of −44.56 dB at 14.52 GHz with a matching thickness of 8 mm, and the maximum absorption bandwidth reaches 5.2 GHz, meeting an intensity criteria for excellent wave-absorbing materials (RLmin<−30 dB). This indicates that the copper-doped silicon carbide composite exhibits superior wave absorption performance.

FIG. 6 shows a graph illustrating the real part value of the dielectric loss of the copper-doped silicon carbide composite prepared in Example 1 of the present disclosure, showing an overall decrease within a testing frequency range (2-18 GHz).

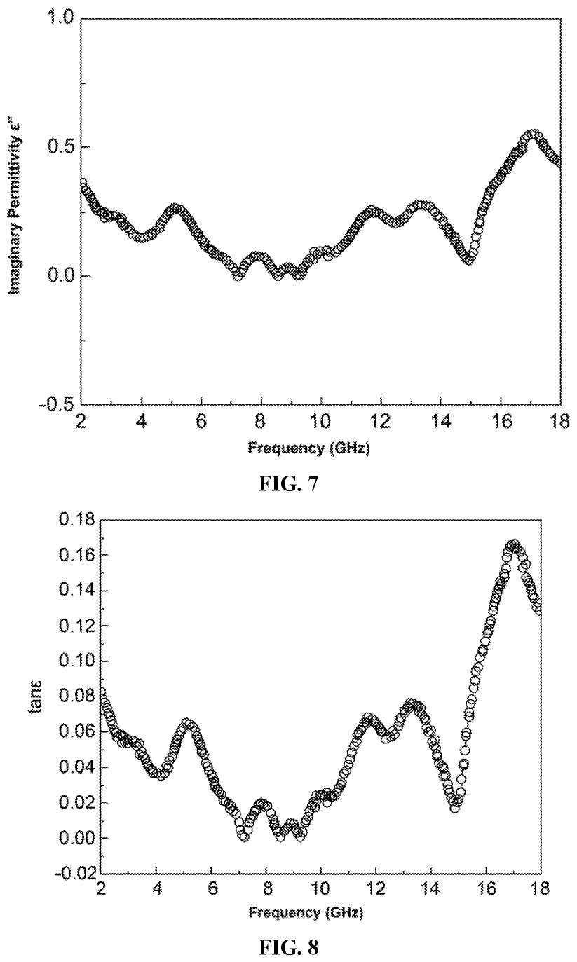

FIG. 7 shows a graph illustrating the imaginary part value of the dielectric loss of the copper-doped silicon carbide composite prepared in Example 1 of the present disclosure, exhibiting a trend of first decreasing within a 2-8 GHz frequency range and then increasing within a 8 -18 GHz range. This indicates that the copper-doped silicon carbide composite exhibits directivity toward high-frequency electric field loss.

FIG. 8 shows a graph illustrating the dielectric loss tangent value of the copper-doped silicon carbide composite prepared in Example 1 of the present disclosure, the value of which increases significantly in a frequency range of 15-17 GHz.

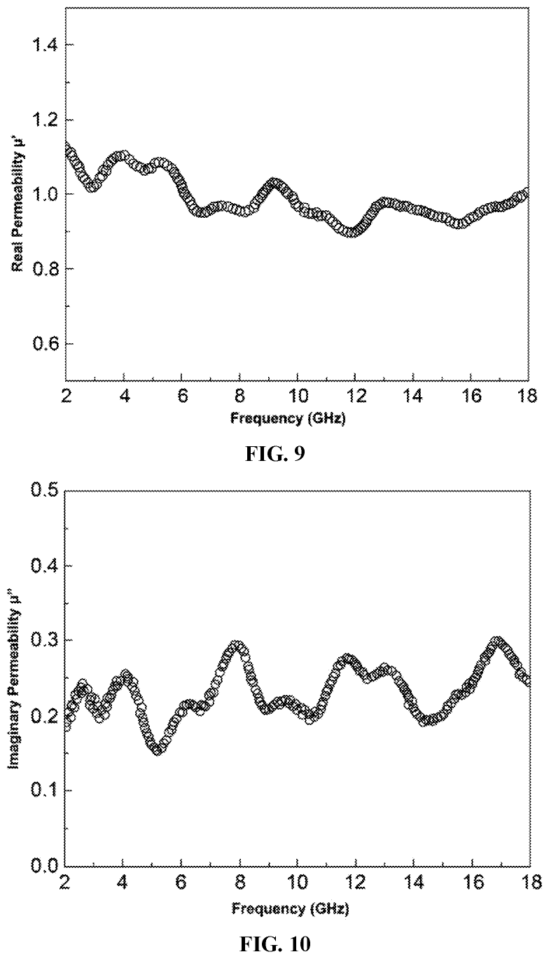

FIG. 9 shows a graph illustrating the real part value of a magnetic loss of the copper-doped silicon carbide composite prepared in Example 1 of the present disclosure, the value of which fluctuates slightly in a frequency range of 2-18 GHz and varies slowly between 0.9-1.1.

FIG. 10 shows a graph illustrating the imaginary part value of the magnetic loss of the copper-doped silicon carbide composite prepared in Example 1 of the present disclosure, the value of which fluctuates significantly in the frequency range of 2-18 GHz.

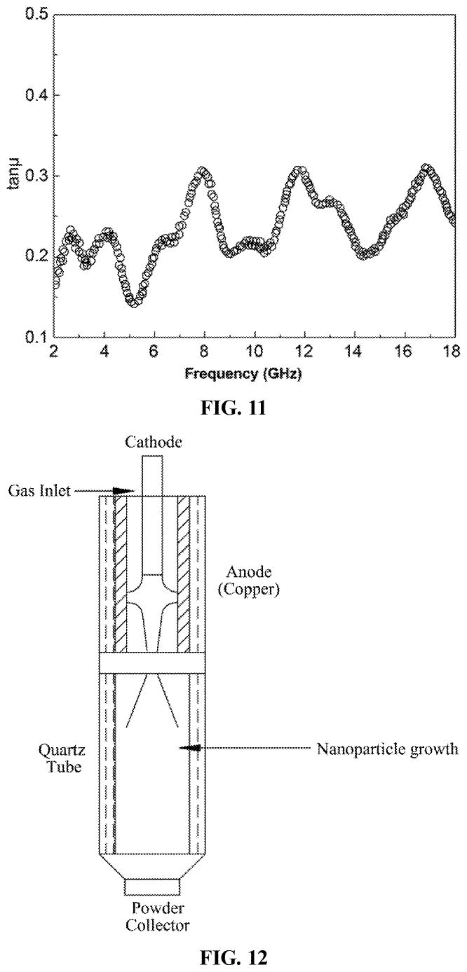

FIG. 11 shows a graph illustrating the imaginary loss tangent value of the copper-doped silicon carbide composite prepared in Example 1 of the present disclosure, the value of which fluctuates significantly in a frequency range of 2-18 GHz.

As shown in FIG. 1 to FIG. 11, the copper-doped silicon carbide composite achieves an RLmin of −44.56 dB at 14.52 GHz with a matching thickness of 8 mm, and the maximum absorption bandwidth reaches 5.2 GHz, meeting the intensity criteria for excellent wave-absorbing materials (RLmin<−30 dB). This indicates that the copper-doped silicon carbide composite exhibits superior wave absorption performance. Meanwhile, the magnetic loss tangent is greater than the dielectric loss tangent, indicating that the magnetic loss of the copper-doped silicon carbide composite dominates its overall energy loss; this indirectly proves that the copper is doped into a nano-silicon carbide composite, resulting in magnetic loss mechanisms similar to those of magnetic materials such as iron, cobalt, and nickel.

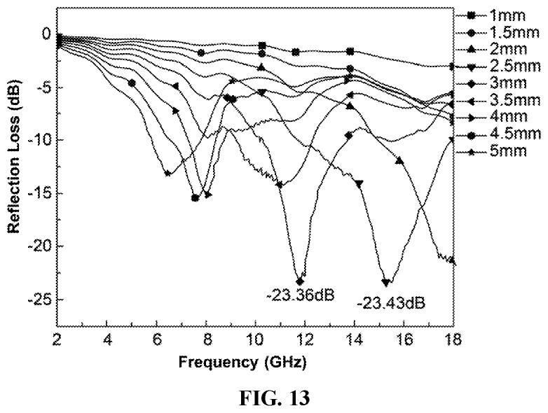

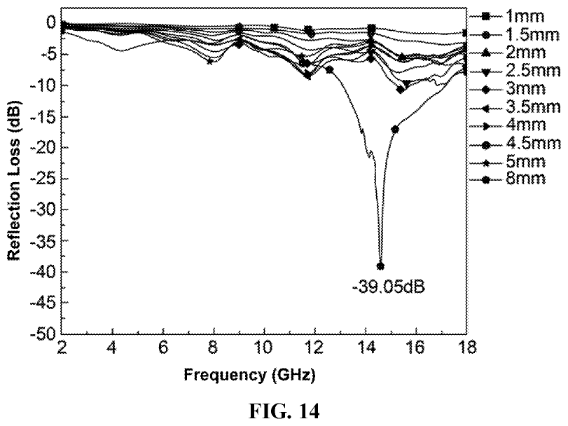

FIG. 13 shows a graph illustrating the reflection loss value of the copper-doped silicon carbide composite prepared in Example 2; and FIG. 14 shows a graph illustrating the reflection loss value of the copper-doped silicon carbide composite prepared in Example 3. As can be seen from FIG. 13 to FIG. 14, the copper-doped silicon carbide composite prepared according to the present disclosure shows excellent microwave absorption performance.

Based on the preparation process and the microwave absorption performance test results of the copper-doped silicon carbide composite, the copper-doped silicon carbide composite prepared under the condition of an arc power of 2.2 kW in Example 1 exhibits the optimal wave absorption performance.

### Examples 4-6 Effect of Different Arc-Striking Atmosphere Gases On Copper Doping Effect

Air in an arc plasma generator was displaced with the argon, and an arc-striking atmosphere gas was continuously introduced at a flow rate of 2 L/min, and a power supply was switched on to ignite an arc within an arc-striking atmosphere gas (which was argon, nitrogen, and helium in Example 4, Example 5, and Example 6, respectively) atmosphere, with an arc power being set at 5 kW. Upon reaching a stable operating state, methyltrichlorosilane from a bubbler was carried, with a feed rate of 0.5 g/min, into the arc plasma generator via the arc-striking atmosphere gas, a resulting material was subjected to pyrolysis to form a gaseous copper-doped silicon carbide, and the gaseous copper-doped silicon carbide was deposited within the arc plasma generator along the direction of the plasma jet and collected to obtain a solid product;

2 g of the solid product was added to 100 mL of a NaOH solution with a concentration of 0.5 mol/L and sonicated for 30 min, followed by suction filtration with simultaneous washing with deionized water. A resulting solid was left to stand in a vacuum oven at 105° C. for 2 h to obtain a copper-doped silicon carbide composite.

According to the test results of Examples 4-6, the copper doping effect under different arc-striking atmosphere gases is similar.

### Examples 7-9 Effect of Different Organochlorosilanes On Copper Doping Effect

Air in an arc plasma generator was displaced with the argon, and argon was continuously introduced at a flow rate of 2 L/min, and a power supply was switched on to ignite an arc within an argon atmosphere, with an arc power being set at 5 kW. Upon reaching a stable operating state, an organochlorosilane (which was methyltrichlorosilane, dimethyldichlorosilane, and trimethylchlorosilane in Example 7, Example 8, and Example 9, respectively) from a bubbler was carried, with a feed rate of 0.5 g/min, into the arc plasma generator via argon, a resulting material was subjected to pyrolysis to form a gaseous copper-doped silicon carbide, and the gaseous copper-doped silicon carbide was deposited within the arc plasma generator along the direction of the plasma jet and collected to obtain a solid product.

2 g of the solid product was added to 100 mL of a NaOH solution with a concentration of 0.5 mol/L and sonicated for 30 min, followed by suction filtration with simultaneous washing with deionized water. A resulting solid was left to stand in a vacuum oven at 105° C. for 2 h to obtain a copper-doped silicon carbide composite.

According to the test results of Examples 7-9, all carbon-containing organochlorosilanes can successfully produce copper-doped silicon carbide composites. Among them, methyltrichlorosilane has a stoichiometric carbon-to-silicon ratio of 1:1, which provides silicon and carbon atoms according to a chemical formula of silicon carbide (SiC), making it as a preferred organochlorosilane raw material.

### Examples 10-12 Effect of Different Feed Rates On Copper Doping Effect

Air in an arc plasma generator was displaced with argon, and the argon was continuously introduced at a flow rate of 2 L/min, and a power supply was switched on to ignite an arc within an argon atmosphere, with an arc power being set at 10 kW. Upon reaching a stable operating state, methyltrichlorosilane from a bubbler was carried, with a feed rate of 0.5 g/min, 1 g/min, 5 g/min in Example 10, Example 11, and Example 12, respectively, into the arc plasma generator via argon, a resulting material was subjected to pyrolysis to form a gaseous copper-doped silicon carbide, and the gaseous copper-doped silicon carbide was deposited within the arc plasma generator along the direction of the plasma jet and collected to obtain a solid product;

2 g of the solid product was added to 100 mL of a NaOH solution with a concentration of 0.5 mol/L and sonicated for 30 min, followed by suction filtration with simultaneous rinsing with deionized water. A resulting solid was left to stand in a vacuum oven at 105° C. for 2 h to obtain a copper-doped silicon carbide composite.

According to the test results of Examples 10-12, for the arc power of 10 kW, the preferred feed rate is 1 g/min, which can ensure copper doping effect while improving energy utilization.

The foregoing descriptions are merely preferred embodiments of the present disclosure, and it should be noted that for those of ordinary skill in the art, without departing from the principles of the present disclosure, some improvements and refinements may also be made, which should also be considered as the scope of the present disclosure.

What is claimed is:

1. A method for preparing a copper-doped silicon carbide composite, comprising:
subjecting a silicon-and carbon-containing precursor to arc plasma pyrolysis to obtain the copper-doped silicon carbide composite, wherein
the silicon-and carbon-containing precursor comprises an organochlorosilane; and
a material of an anode used for the arc plasma pyrolysis comprises copper.

2. The method of claim 1, wherein the arc plasma pyrolysis is conducted with an arc power of 1-100 kW.

3. The method of claim 1, wherein an arc-striking atmosphere gas for the arc plasma pyrolysis comprises at least one selected from the group consisting of argon, nitrogen, hydrogen and helium.

4. The method of claim 3, wherein a flow rate of the arc-striking atmosphere gas is in a range of 0.2-30 L/min.

5. The method of claim 1, wherein the organochlorosilane comprises at least one selected from the group consisting of methyltrichlorosilane, dimethyldichlorosilane, and trimethylchlorosilane.

6. The method of claim 1, wherein a feed rate of the silicon-and carbon-containing precursor is in a range of 0.1-2000 g/min.

7. The method of claim 1, wherein after the arc plasma pyrolysis, the method further comprises subjecting a resulting solid product to alkaline washing and drying in sequence to obtain the copper-doped silicon carbide composite.

8. A copper-doped silicon carbide composite prepared by the method of any one of claims 1.

9. The copper-doped silicon carbide composite of claim 8, wherein silicon carbide in the copper-doped silicon carbide composite has a β-type crystal form.

10. The copper-doped silicon carbide composite of claim 8, wherein the copper-doped silicon carbide composite has a particle size of 20-500 nm.

11. The copper-doped silicon carbide composite of 10, wherein copper in the copper-doped silicon carbide composite is doped in a SiC lattice in a form of a copper-silicon solid solution; and
the copper-silicon solid solution comprises Cu_{6.69}Si and/or Cu₃Si.

12. The method of claim 5, wherein a feed rate of the silicon-and carbon-containing precursor is in a range of 0.1-2000 g/min.

13. The copper-doped silicon carbide composite of claim 8, wherein the arc plasma pyrolysis is conducted with an arc power of 1-100 kW.

14. The copper-doped silicon carbide composite of claim 8, wherein an arc-striking atmosphere gas for the arc plasma pyrolysis comprises at least one selected from the group consisting of argon, nitrogen, hydrogen and helium.

15. The copper-doped silicon carbide composite of claim 8, wherein a flow rate of the arc-striking atmosphere gas is in a range of 0.2-30 L/min.

16. The copper-doped silicon carbide composite of claim 8, wherein the organochlorosilane comprises at least one selected from the group consisting of methyltrichlorosilane, dimethyldichlorosilane, and trimethylchlorosilane.

17. The copper-doped silicon carbide composite of claim 8, wherein a feed rate of the silicon-and carbon-containing precursor is in a range of 0.1-2000 g/min.

18. The copper-doped silicon carbide composite of claim 8, wherein after the arc plasma pyrolysis, the method further comprises subjecting a resulting solid product to alkaline washing and drying in sequence to obtain the copper-doped silicon carbide composite.

19. The copper-doped silicon carbide composite of claim 9, wherein the copper-doped silicon carbide composite has a particle size of 20-500 nm.
